(19) United States
(12) Patent Application Publication
(10) Pub. No.: US 2009/0167386 A1
(43) Pub. Date: Jul. 2, 2009

(54) Charge pumping circuit, clock synchronization circuit having the charge pumping circuit, and method for operating the clock synchronization circuit

(76) Inventor: Taek-Sang Song, Kyoungki-do (KR)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/150,707

(22) Filed: Apr. 29, 2008

(30) Foreign Application Priority Data
Dec. 27, 2007 (KR) 2007-0138923

(51) Int. Cl. H03L 7/06; H02M 3/18

(52) U.S. Cl. 327/157; 363/59

(57) ABSTRACT

A charge pumping circuit includes a first charge pump configured to perform a charge pumping operation on an output terminal in response to a first pumping control signal, an auxiliary charge pumping controller configured to generate a second pumping control signal activated during a predetermined section of an activation period of the first pumping control signal and a second charge pump configured to perform a charge pumping operation on the output terminal in response to the second pumping control signal.

### CROSS-REFERENCE TO RELATED APPLICATIONS

The present invention claims priority of Korean patent application number 10-2007-0138923, filed on Dec. 27, 2007, which is incorporated by reference in its entirety.

### BACKGROUND OF THE INVENTION

The present invention relates to a semiconductor device, and more particularly, to a charge pumping circuit, a clock synchronization circuit having the charge pumping circuit, and a method for operating the clock synchronization circuit.

In semiconductor devices such as double data rate (DDR) synchronous dynamic random access memory (SDRAM), an external clock is used as a reference for matching operation timings. A clock synchronization circuit is provided within the semiconductor device in order to generate an internal clock signal synchronized with an external clock. Examples of the clock synchronization circuit include a phase locked loop (PLL) and a delay locked loop (DLL).

The configuration of the PLL is basically similar to that of the DLL. The PLL uses a voltage controlled oscillator (VCO) to generate an internal clock, while the DLL uses a voltage controlled delay line (VCDL).

FIG. 1 is a block diagram of a typical PLL.

Referring to FIG. 1, an analog type PLL includes a phase/frequency detector 110, a charge pump 130, a control voltage generator 150, and a VCO 170. The phase/frequency detector 110 detects a phase/frequency difference between a reference clock signal CLK_REF and a feedback clock signal CLK_FED to generate an up detection signal DET_UP and a down detection signal DET_DN corresponding to the detected phase/frequency difference. The reference clock CLK_REF is a signal corresponding to an external clock. The up detection signal DET_UP and the down detection signal DET_DN are pulse signals activated according to the phase/frequency relation of the reference clock signal CLK_REF and the feedback clock signal CLK_FED, which will be described later.

The charge pump 130 performs a positive charge pumping operation in response to the up detection signal DET_UP, and performs a negative charge pumping operation in response to the down detection signal DET_DN. That is, the charge pump 130 charges electric charges to the control voltage generator 150 through an output terminal I_CP in response to the up detection signal DET_UP, and discharges electric charges accumulated in the control voltage generator 150 through the output terminal I_CP in response to the down detection signal DET_DN.

The control voltage generator 150 charges electric charges as much as a current supplied by the positive charge pumping operation of the charge pump 130, and generates an oscillation control voltage V_CTR corresponding to the charged electric charges. In addition, the control voltage generator 150 discharges electric charges as much as a current reduced by the negative charge pumping operation of the charge pump 130, and generates the oscillation control voltage V_CTR corresponding to the discharged electric charges. In other words, a voltage level of the oscillation control voltage V_CTR is increased by the positive charge pumping operation of the charge pump 130, and is decreased by the negative charge pumping operation of the charge pump 130.

The VCO 170 generates a PLL clock signal CLK_PLL having a frequency corresponding to the voltage level of the oscillation control voltage V_CTR. The PLL clock signal CLK_PLL is used as the feedback clock signal CLK_FED fed back to the phase/frequency detector 110. The phase/frequency detector 110 generates the up detection signal DET_UP and the down detection signal DET_DN corresponding to the phase/frequency difference between the reference clock signal CLK_REF and the feedback clock signal CLK_FED.

An operation of the PLL will be described briefly.

The phase/frequency detector 110 detects the phase/frequency difference between the reference clock signal CLK_REF and the feedback clock signal CLK_FED and generates the up detection signal DET_UP and the down detection signal DET_DN. The up detection signal DET_UP is a pulse signal activated when the phase of the feedback signal CLK_FED lags behind the phase of the reference clock CLK_REF, and it has a pulse width corresponding to the phase difference between the feedback signal CLK_FED and the reference clock CLK_REF. The down detection signal DET_DN is a pulse signal enabled when the phase of the feedback signal CLK_FED leads the phase of the reference clock CLK_REF, and it has a pulse width corresponding to the phase difference between the feedback signal CLK_FED and the reference clock CLK_REF.

The charge pump 130 charges or discharges the control voltage generator 150 through the charge pumping operation according to the up detection signal DET_UP and the down detection signal DET_DN. Therefore, the voltage level of the oscillation control voltage V_CTR output from the control voltage generator 150 is changed. In other words, the voltage level of the oscillation control voltage V_CTR is increased in response to the up detection signal DET_UP, and it is decreased in response to the down detection signal DET_DN.

The VCO 170 generates the PLL clock signal CLK_PLL having a low frequency when the oscillation control voltage V_CTR is at a high voltage level, and it generates the PLL clock signal CLK_PLL having a high frequency when the oscillation control voltage V_CTR is at a low voltage level.

The relationship between the voltage level of the oscillation control voltage V_CTR and the frequency of the PLL clock signal CLK_PLL may be changed according to their design. That is, the VCO 170 can generate the PLL clock signal CLK_PLL having a low frequency when the oscillation control voltage V_CTR is at a low voltage level and generate the PLL clock signal CLK_PLL having a high frequency when the oscillation control voltage V_CTR is at a high voltage level.

The feedback clock signal CLK_FED is a PLL clock signal CLK_PLL fed back to the phase/frequency detector 110, and the phase/frequency detector 110 again detects the phase/frequency difference between the reference clock signal CLK_REF and the feedback clock signal CLK_FED with the changed frequency.

The PLL repeats the above-described operation to output the PLL clock signal CLK_PLL synchronized with the reference clock signal CLK_REF. The synchronization of the reference clock signal CLK_REF and the PLL clock signal CLK_PLL is referred to as a “locking”. A time necessary for the PLL to be locked at an initial state is referred to as a “locking time”. The reference clock signal CLK_REF is not synchronized with the PLL clock signal CLK_PLL prior to the locking of the PLL. In other words, the PLL can generate the stable PLL clock signal CLK_PLL after the locking time, and the semiconductor device can use the stable PLL clock signal CLK_PLL after the locking time.

FIG. 2 is a circuit diagram of the charge pump 130 of FIG. 1.

Referring to FIG. 2, the charge pump 130 includes a first current source 210 and a second current source 230.

The first current source 210 performs the positive charge pumping operation in response to the up detection signal DET_UP. During the positive charge pumping operation, the first current source 210 charges the control voltage generator 150 by transferring electric charges supplied from a power supply voltage terminal VDD to the output terminal I_CP.

The second current source 230 performs the negative charge pumping operation in response to the down detection signal DET_DN. During the negative charge pumping operation, the second current source 230 discharges the supplied electric charges to a ground voltage terminal VSS.

An amount of a current flowing through the output terminal I_CP during the positive charge pumping operation of the first current source 210 and an amount of a current flowing through the output terminal I_CP during the negative charge pumping operation of the second current source 230 are an important factor in determining the locking time. That is, the locking time becomes shorter as an amount of a current flowing through the output terminal I_CP is larger, and the locking time becomes longer as an amount of a current flowing through the output terminal I_CP.

To meet users' demand, semiconductor devices are designed to operate at higher speed. Under these circumstances, the reduction of the locking time is an important issue. However, in the design of the charge pump, it is difficult to increase an amount of a current at which the charge pump 130 can be driven so as to reduce the locking time. The reasons are as follows.

The PLL is a closed-loop system having two poles at an origin in a frequency domain (s-domain). It is difficult to ensure a desired phase margin in the locking operation.

The “pole” is a value that makes a denominator zero in a transfer function of a system, and “zero” is a value that makes a numerator zero in the transfer function of the system. The pole and the zero are an important factor in determining a phase margin of the system. The pole and the zero are a barometer in determining a stable or unstable degree of the system.

Next, the phase margin will be described below.

When a phase margin of a system is 60 degrees, a signal oscillating in a time domain can reach a steady state within a minimal time. When the phase margin of the system is less than 60 degrees, a response time may be fast, but an unstable degree may increase. Thus, it may take a long time for the oscillating signal to reach the steady state. On the contrary, when the phase margin of the system is greater than 60 degrees, the stability is high, but the response time is slow. Thus, it may take a long time for the oscillating signal to reach the steady state.

An amount of a current driven in the charge pump 130 is an important factor in determining the phase margin of the PLL. That is, if an amount of a current driven in the charge pump 130 increases in order to reduce the locking time, the phase margin of the PLL is reduced, degrading the stability of the PLL. Furthermore, an operation characteristic with respect to jitters of the PLL, that is, bandwidth, is degraded. Since these problems generally occur in the PLL, detailed description about the causes of the problems will be omitted.

Therefore, there is a need for an improved charge pumping circuit that can solve the problems.

### SUMMARY OF THE INVENTION

Embodiments of the present invention are directed to providing a clock synchronization circuit having a fast locking time without degradation in a phase margin or operation characteristic with respect to jitters.

In accordance with an aspect of the present invention, there is provided a first charge pump configured to perform a charge pumping operation on an output terminal in response to a first pumping control signal, an auxiliary charge pumping controller configured to generate a second pumping control signal activated during a predetermined section of an activation period of the first pumping control signal and a second charge pump configured to perform a charge pumping operation on the output terminal in response to the second pumping control signal.

Many attempts have been made to reduce a locking time of a clock synchronization circuit. One approach to reducing the locking time is to increase a driving current of the charge pump. However, this approach degrades a phase margin and thus it is difficult to design. To solve this problem, two charge pumps are provided in the charge pumping circuit. Therefore, when the phase difference between a reference clock signal and a feedback clock signal is large, two charge pumps are operated to thereby reduce the locking time. When the phase difference between the reference clock signal and the feedback clock signal is small, one charge pump is operated to obtain a desired phase margin and operation characteristic with respect to jitters.

### BRIEF DESCRIPTION OF THE DRAWINGS

FIG. 1 is a block diagram of a typical PLL.

FIG. 2 is a circuit diagram of a charge pump (130) of FIG. 1.

FIG. 3 is a block diagram of a charge pumping circuit in accordance with an embodiment of the present invention.

FIG. 4 is a circuit diagram of an auxiliary charge pumping controller (350) of FIG. 3.

FIGS. 5A and 5B are timing diagrams of signals used in the charge pumping circuit of FIG. 3.

FIG. 6 is a block diagram of a PLL using the charge pumping circuit of FIG. 3 in accordance with an embodiment of the present invention.

FIG. 7 is a graph for explaining a current (I_CP_SUM) flowing through the output terminal (I_CP) according to a phase difference between a reference clock signal (CLK_REF) and a feedback clock signal (CLK_FED).

FIG. 8 is a timing diagram for explaining the locking time in the locking of the PLL of FIG. 6.

FIG. 9 is a block diagram of a delay locked loop (DLL) using the charge pumping circuit of FIG. 3.

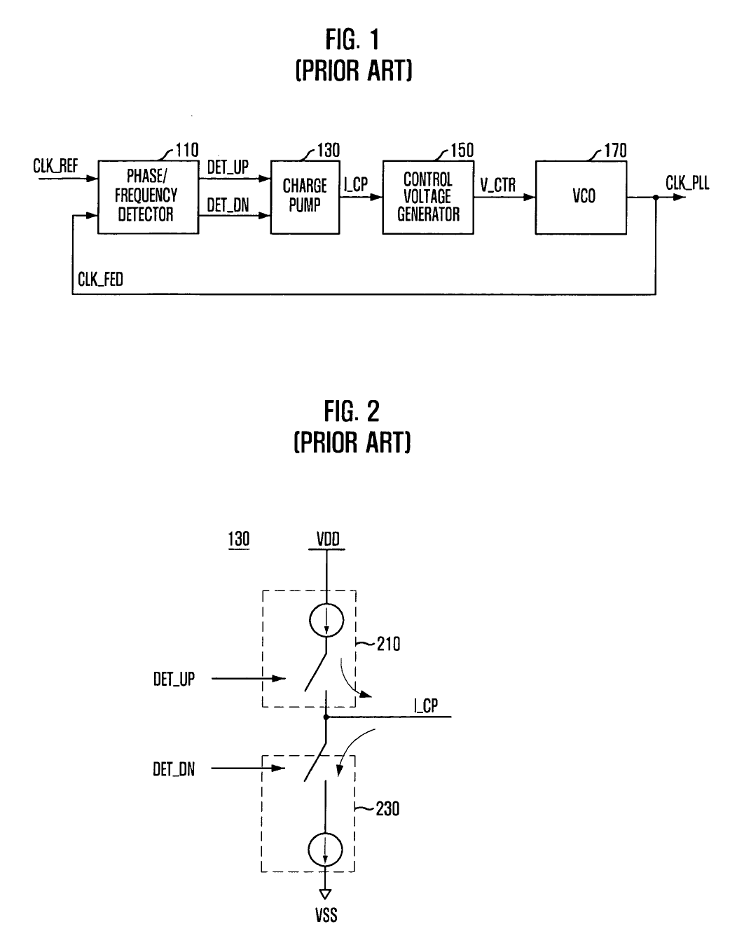

### DESCRIPTION OF SPECIFIC EMBODIMENTS

Hereinafter, a charge pumping circuit, a clock synchronization circuit having the charge pumping circuit, and a method for operating the clock synchronization circuit in accordance with the present invention will be described in detail with reference to the accompanying drawings.

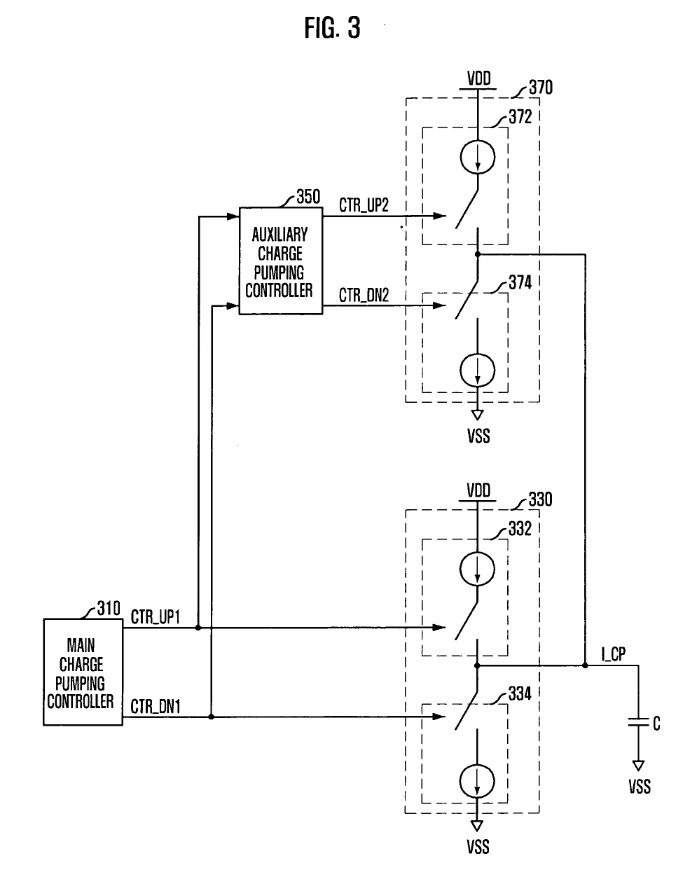

FIG. 3 is a block diagram of a charge pumping circuit in accordance with an embodiment of the present invention. For convenience of explanation, a capacitor C between an output terminal I_CP and a ground voltage terminal VSS is illustrated in FIG. 3.

Referring to FIG. 3, the charge pumping circuit includes a main charge pumping controller 310, a first charge pump 330, an auxiliary charge pumping controller 350, and a second charge pump 370.

The main charge pumping controller 310 generates a first up pumping control signal CTR_UP1 and a first down pumping control signal CTR_DN1, which are pulse signals having an activation period longer than a predefined section. The first up pumping control signal CTR_UP1 is a signal for enabling the first charge pump 330 to perform a positive charge pumping operation, and the first down pumping control signal CTR_DN1 is a signal for enabling the first charge pump 330 to perform a negative charge pumping operation. Ideally, the activation period of the first up pumping control signal CTR_UP1 should not be overlapped with the activation period of the first down pumping control signal CTR_DN1. That is, the positive charge pumping operation and the negative charge pumping operation of the first charge pump 330 should be independently performed.

The first charge pump 330 performs a charge pumping operation on the output terminal I_CP in response to the first up pumping control signal CTR_UP1 and the first down pumping control signal CTR_DN1. The first charge pump 330 may include a first current source 332 and a second current source 334.

The first current source 332 performs the positive charge pumping operation in response to the first up pumping control signal CTR_UP1. During the positive charge pumping operation, the first current source 332 charges a capacitor by transferring electric charges supplied from a power supply voltage terminal VDD to the output terminal I_CP.

The second current source 334 performs the negative charge pumping operation in response to the first down pumping control signal CTR_DN1. During the negative charge pumping operation, the second current source 334 discharges the supplied electric charges from the capacitor C to a ground voltage terminal VSS.

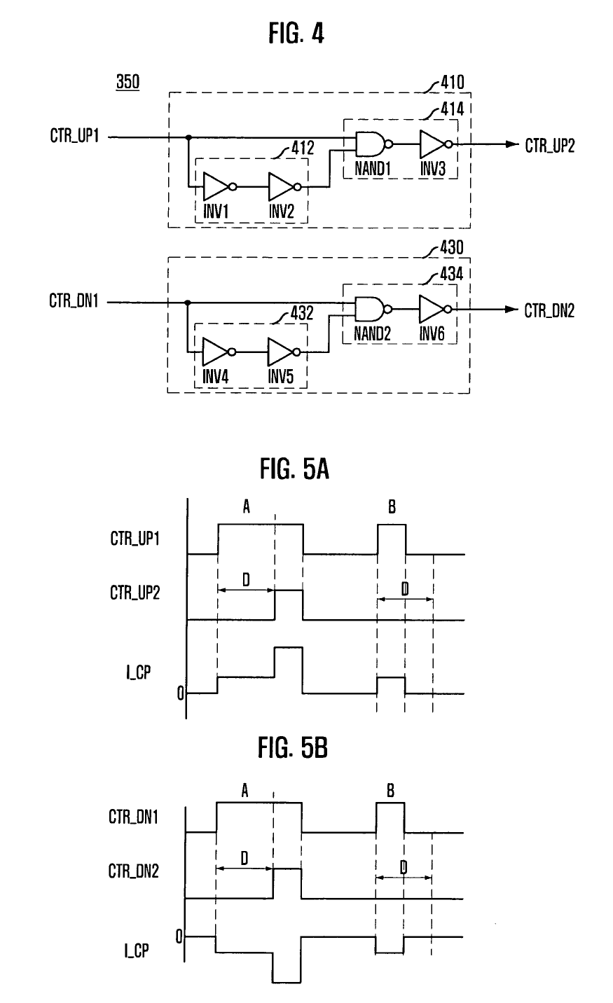

The auxiliary charge pumping controller 350 generates a second up pumping control signal CTR_UP2 and a second down pumping control signal CTR_DN2 that are respectively activated during predetermined sections of the activation periods of the first up pumping control signal CTR_UP1 and the first down pumping control signal CTR_DN1. The second up pumping control signal CTR_UP2 is a signal for enabling the second charge pump 370 to perform the positive charge pumping operation, and the second down pumping control signal CTR_DN2 is a signal for enabling the second charge pump 370 to perform the negative charge pumping operation. The circuit configuration of the auxiliary charge pumping controller 350 will be described later with reference to FIG. 4.

The second charge pump 370 performs a charge pumping operation on the output terminal I_CP in response to the second up pumping control signal CTR_UP2 and the second down pumping control signal CTR_DN2. The second charge pump 370 may include a third current source 372 and a fourth current source 374.

The third current source 372 performs the positive charge pumping operation in response to the second up pumping control signal CTR_UP2. During the positive charge pumping operation, the third current source 372 charges the capacitor by transferring electric charges supplied from the power supply voltage terminal VDD to the output terminal I_CP.

The fourth current source 374 performs the negative charge pumping operation in response to the second down pumping control signal CTR_DN2. During the negative charge pumping operation, the fourth current source 374 discharges the supplied electric charges from the capacitor C to the ground voltage terminal VSS.

The first charge pump 330 performs the charge pumping operation in the activation periods of the first up pumping control signal CTR_UP1 and the first down pumping control signal CTR_DN1, and the second charge pump 370 performs the charge pumping operation during the predetermined sections of the activation periods of the first up pumping control signal CTR_UP1 and the first down pumping control signal CTR_DN1. That is, when the activation period of the first charge pump 330 is longer than the predefined section, the second charge pump 370 is enabled to pump a larger amount of a current to the capacitor C.

FIG. 4 is a circuit diagram of the auxiliary charge pumping controller 350 of FIG. 3.

Referring to FIG. 4, the auxiliary charge pumping controller 350 includes a first pulse generating unit 410 and a second pulse generating unit 430.

The first pulse generating unit 410 generates the second up pumping control signal CTR_UP2 activated during the predetermined section of the activation period of the first up pumping control signal CTR_UP1. The first pulse generating unit 410 may include a first delay unit 412 and a first output unit 414.

The first delay unit 412 delays the first up pumping control signal CTR_UP1 by the predefined section. The first delay unit 412 may include a first inverter INV1 and a second inverter INV2.

The first output unit 414 receives output the first up pumping control signal CTR_UP1 and an output signal of the first delay unit 412 to generate the second up pumping control signal CTR_UP2. The first output unit 414 includes a first NAND gate NAND1 and a third inverter INV3.

The second up pumping control signal CTR_UP2 is activated when the activation period of the first up pumping control signal CTR_UP1 is longer than the predefined section reflected by the first delay unit 412. The second up pumping control signal CTR_UP2 is a pulse signal corresponding to the overlap section of the first up pumping control signal CTR_UP1 and the output signal of the first delay unit 412.

The second pulse generating unit 430 generates the second down pumping control signal CTR_DN2 activated during the predetermined section of the activation period of the first down pumping control signal CTR_DN1. The second pulse generating unit 430 may include a second delay unit 432 and a second output unit 434.

The second delay unit 432 delays the first down pumping control signal CTR_DN1 by the predefined section. The second delay unit 432 may include a fourth inverter INV4 and a fifth inverter INV5.

The second output unit 434 receives output the first down pumping control signal CTR_DN1 and an output signal of the second delay unit 432 to generate the second down pumping control signal CTR_DN2. The second output unit 434 includes a second NAND gate NAND1 and a sixth inverter INV6.

The second down pumping control signal CTR_DN2 is activated when the activation period of the first down pumping control signal CTR_DN1 is longer than the predefined section reflected by the second delay unit 432. The second down pumping control signal CTR_DN2 is a pulse signal corresponding to the overlap section of the first down pumping control signal CTR_DN1 and the output signal of the second delay unit 432.

The first charge pump 330 performs the positive charge pumping operation in response to the first up pumping control signal CTR_UP1 activated with the pulse width longer than the predefined section. At this point, the second charge pump 370 performs the positive charge pumping operation in response to the second up pumping control signal CTR_UP2 activated during the predetermined section after the predefined section of the first up pumping control signal CTR_UP1.

Likewise, the first charge pump 330 performs the negative charge pumping operation in response to the first down pumping control signal CTR_DN1 activated with the pulse width longer than the predefined section. At this point, the second charge pump 370 performs the negative charge pumping operation in response to the second up pumping control signal CTR_UP2 activated during the predetermined section after the predefined section of the first down pumping control signal CTR_DN1.

FIGS. 5A and 5B are timing diagrams of the signals used in the charge pumping circuit of FIG. 3.

Specifically, FIG. 5A is a timing diagram of the first up pumping control signal CTR_UP1 and the second up pumping control signal CTR_UP2 with relation to the positive charge pumping operation, and FIG. 5B is a timing diagram of the first down pumping control signal CTR_DN1 and the second down pumping control signal CTR_DN2 with relation to the negative charge pumping operation. For convenience of explanation, a following description will be focused on the timing diagram of FIG. 5A, but the timing diagram of FIG. 5B will be understood from the description of FIG. 5A.

Referring to FIG. 5A, the first up pumping control signal CTR_UP1 may have the activation period longer or shorter than the predefined section D. The former will be referred to as a case A, and the latter will be referred to as a case B.

In the case A, the second up pumping control signal CTR_UP2 is activated during the predetermined section of the activation period of the first up pumping control signal CTR_UP1. Thus, the first charge pump 330 of FIG. 3 performs the positive charge pumping operation in response to the first up pumping control signal CTR_UP1 and, after the predefined section A, the second charge pump 370 additionally performs the positive charge pumping operation in response to the second up pumping control signal CTR_UP2. As can be seen from FIG. 5A, the second up pumping control signal CTR_UP2 is activated after the predefined section D from the activated time point of the first up pumping control signal CTR_UP1 and is deactivated at the deactivated time point of the first up pumping control signal CTR_UP1. Consequently, a current due to the first up pumping control signal CTR_UP1 is supplied to the output terminal I_CP during the predefined section D and thereafter much more current due to the first up pumping control signal CTR_UP1 and the second up pumping control signal CTR_UP2 are supplied.

In the case B, the second up pumping control signal CTR_UP2 is not activated. Thus, only the first charge pump 330 performs the positive charge pumping operation in response to the first up pumping control signal CTR_UP1. Consequently, only a current due to the first up pumping control signal CTR_UP1 is supplied to the output terminal I_CP.

The charge pumping circuit in accordance with the embodiment of the present invention compares the activation period of the first up pumping control signal CTR_UP1 with the predefined section D and additionally performs the positive charge pumping operation by activating the second up pumping control signal CTR_UP2 when the activation period of the first up pumping control signal CTR_UP1 is longer than the predefined section D.

Referring to FIG. 5B, the charge pumping circuit compares the activation period of the first down pumping control signal CTR_DN1 with the predefined section D and additionally performs the negative charge pumping operation by activating the second down pumping control signal CTR_DN2 when the activation period of the first down pumping control signal CTR_DN1 is longer than the predefined section D. In addition, when the activation periods of the first up/down pumping control signals CTR_UP1 and CTR_DN1 are shorter than the predefined section D, only the first charge pump 330 performs the negative charge pumping operation because the second up/down pumping control signals CTR_UP2 and CTR_DN2 are not activated.

Therefore, the charge pumping circuit in accordance with the embodiment of the present invention can ensure a fast locking time by applying it to the clock synchronization circuit, without degradation in the phase margin or operation characteristic with respect to jitters. That is, by increasing an amount of a current flowing in the charge pumping operation prior to the locking, a much faster locking time can be ensured. Then, by making a constant amount of a current flow in the charge pumping operation, the phase margin or the operation characteristic with respect to the jitters can be ensured.

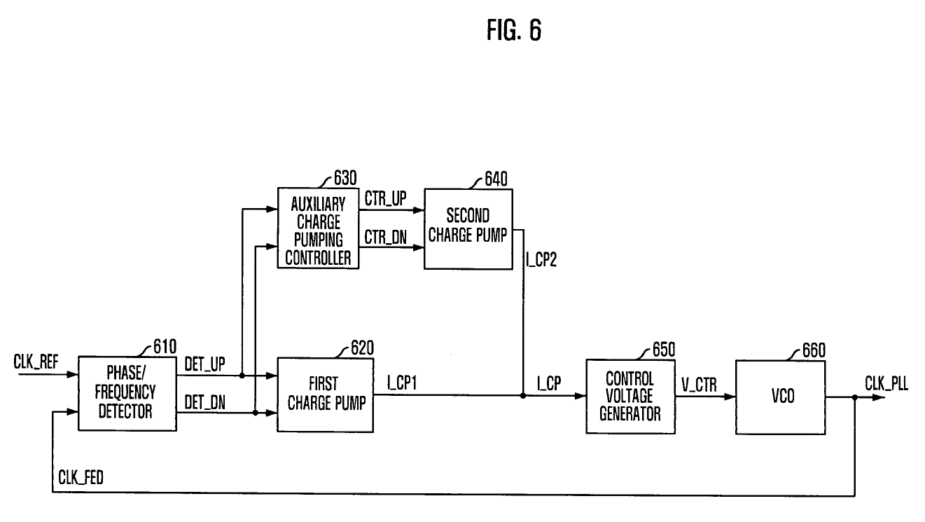

FIG. 6 is a block diagram of a PLL using the charge pumping circuit of FIG. 3 in accordance with an embodiment of the present invention. A first charge pump 620, an auxiliary charge pumping controller 630, and a second charge pump 640 of FIG. 6 correspond to the first charge pump 330, the auxiliary charge pumping controller 350, and the second charge pump 370 of FIG. 3. Since their circuit configurations and operations are identical to each other, their detailed description will be omitted. Although the up/down detection signals DET_UP and DET_DN of FIG. 6 are pulse signals like the first up/down pumping control signals CTR_UP1 and CTR_DN1, a circuit configuration of a phase/frequency detector 610 is different from that of the main charge pumping controller 310.

Referring to FIG. 6, the PLL includes a phase/frequency detector 610, a first charge pump 620, an auxiliary charge pumping controller 630, a second charge pump 640, a control voltage generator 659, and a VCO 660.

The phase/frequency detector 610 detects a phase/frequency difference between a reference clock signal CLK_REF and a feedback clock signal CLK_FED to generate an up detection signal DET_UP and a down detection signal DET_DN corresponding to the detected phase/frequency difference. The reference clock CLK_REF is a signal corresponding to an external clock. The up detection signal DET_UP is a pulse signal activated when the phase of the feedback signal CLK_FED lags behind the phase of the reference clock CLK_REF, and it has a pulse width corresponding to the phase difference between the feedback signal CLK_FED and the reference clock CLK_REF. The down detection signal DET_DN is a pulse signal enabled when the phase of the feedback signal CLK_FED leads the phase of the reference clock CLK_REF, and it has a pulse width corresponding to the phase difference between the feedback signal CLK_FED and the reference clock CLK_REF. For reference, the activation period of the up detection signal DET_UP should not be overlapped with the activation period of the down detection signal DET_DN. However, the PLL may be designed to allow a slight overlap section in order to increase the stability of the circuit operation.

The first charge pump 620 performs a positive charge pumping operation on an output terminal I_CP in response to the up detection signal DET_UP, and performs a negative charge pumping operation on the output terminal I_CP in response to the down detection signal DET_DN. That is, the first charge pump 620 charges the control voltage generator 650 in response to the up detection signal DET_UP, and discharges the control voltage generator 650 in response to the down detection signal DET_DN.

The auxiliary charge pumping controller 630 generates an up pumping control signal CTR_UP, which is activated during a predetermined section of the activation period of the up detection signal DET_UP, and a down pumping control signal CTR_DN, which is activated during a predetermined section of the activation period of the down detection signal DET_DN. That is, the up pumping control signal CTR_UP is a pulse signal activated from a time point where the activation period of the up detection signal DET_UP is longer than the predefined section to a deactivation time point of the up detection signal DET_UP. The down pumping control signal CTR_DN is a pulse signal activated from a time point where the activation period of the up detection signal DET_UP is longer than the predefined section to a deactivation time point of the up detection signal DET_UP.

The second charge pump 640 performs the positive charge pumping operation on the output terminal I_CP in response to the up pumping control signal CTR_UP, and performs the negative charge pumping operation on the output terminal I_CP in response to the down pumping control signal CTR_DN.

The control voltage generator 650 generates an oscillation control voltage V_CTR having a voltage level determined by the charge pumping operations of the first and second charge pumps 620 and 640. That is, the control voltage generator 650 charges electric charges in the positive charge pumping operation to generate the oscillation control voltage V_CTR of a high voltage level, and discharges electric charges in the negative charge pumping operation to generate the oscillation control voltage V_CTR of a low voltage level.

The VCO 660 generates a PLL clock signal CLK_PLL having a frequency corresponding to the voltage level of the oscillation control voltage V_CTR. The PLL clock signal CLK_PLL is used as the feedback clock signal CLK_FED fed back to the phase/frequency detector 610. The phase/frequency detector 610 again generates the up detection signal DET_UP and the down detection signal DET_DN corresponding to the phase/frequency difference between the reference clock signal CLK_REF and the feedback clock signal CLK_FED.

Prior to the locking of the PLL, especially when the phase difference between the reference clock signal CLK_REF and the feedback clock signal CLK_FED is large, much current flows through the output terminal I_CP by the charge pumping operations of the first and second charge pumps 620 and 640. Thereafter, a stable current flows through the output terminal I_CP by the charge pumping operation of the first charge pump 620. Consequently, the PLL in accordance with the embodiment of the present invention can ensure a fast locking time without degradation in a phase margin or operation characteristic with respect to jitters.

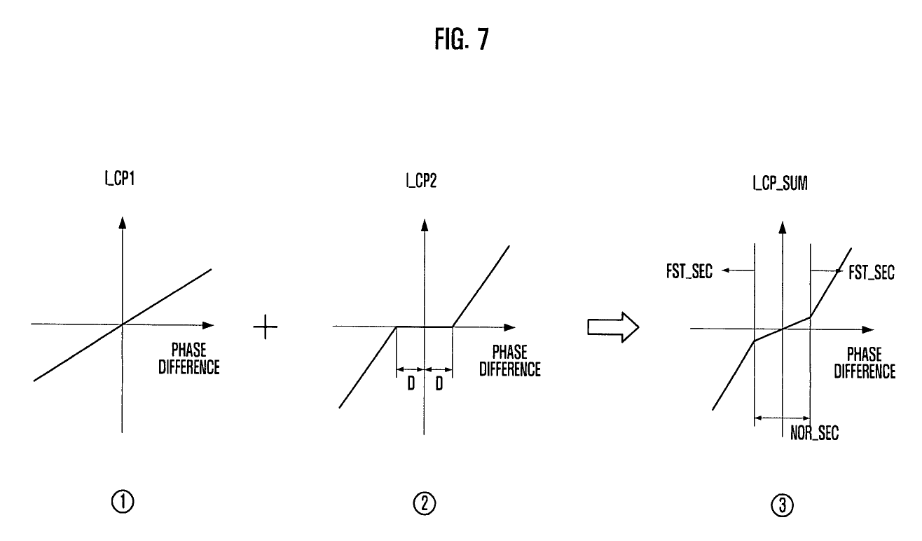

FIG. 7 is a graph for explaining a current I_CP_SUM flowing through the output terminal I_CP according to a phase difference between the reference clock signal CLK_REF and the feedback clock signal CLK_FED. In the graphs \textcircled{1}, \textcircled{2} and \textcircled{3}, a horizontal axis represents the phase difference between the reference clock signal CLK_REF and the feedback clock signal CLK_RED.

The graph \textcircled{1} shows a case where only the first charge pump 620 performs the charge pumping operation. In the graph \textcircled{1}, a vertical axis represents a current I_CP1 according to the charge pumping operation of the first charge pump 620. Like the related art, as the phase difference between the reference clock signal CLK_REF and the feedback clock signal CLK_FED is larger, the current I_CP1 flowing through the output terminal I_CP increases.

The graph \textcircled{2} shows a case where only the second charge pump 640 performs the charge pumping operation. In the graph \textcircled{2}, a vertical axis represents a current I_CP2 according to the charge pumping operation of the second charge pump 640. As can be seen from the graph \textcircled{2}, no current flows through the output terminal I_CP when the phase difference between the reference clock signal CLK_REF and the feedback clock signal CLK_FED is contained in the predefined section D. On the other hand, an amount of a current I_CP2 flowing through the output terminal I_CP gradually increases when the phase difference between the reference clock signal CLK_REF and the feedback clock signal CLK_RED is farther away from the predefined section D. At this point, a slope of the current I_CP2 may be changed according to the design of the second charge pump 640.

The graph \textcircled{3} shows a case where both the first charge pump 620 and the second charge pump 640 perform the charge pumping operations. In the graph \textcircled{3}, a vertical axis represents a current I_CP_SUM flowing through the output terminal I_CP according to the charge pumping operations of the first and second charge pumps 620 and 640. The current I_CP_SUM is equal to a sum of the current I_CP1 and the current I_CP2. As can be seen from the graph \textcircled{3}, only the stable current I_CP1 generated by the first charge pump 620 flows through the output terminal I_CP in a normal operation section NOR_SEC where the locking of the reference clock signal CLK_REF and the feedback clock signal CLK_RED is achieved, and a current I_CP_SUM (=I_CP1+I_CP2) more than that generated by the first and second charge pumps 620 and 640 flows through the output terminal I_CP in a fast operation section where the phase difference between the reference clock signal CLK_REF and the feedback clock signal CLK_FED is large.

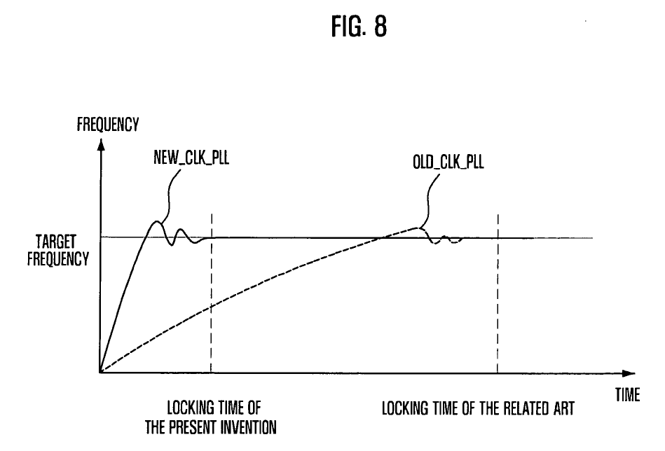

FIG. 8 is a timing diagram for explaining the locking time in the locking of the PLL of FIG. 6. For reference, the PLL has a target frequency of a PLL clock CLK_PLL to be finally output.

As can be seen from FIG. 8, the PLL clock signal NEW_CLK_PLL in accordance with the embodiment of the present invention reaches the target frequency in a shorter time than the conventional PLL clock signal OLD_CLK_PLL. When the phase difference between the reference clock signal CLK_REF and the feedback clock signal CLK_FED is large, the first and second charge pumps 620 and 640 simultaneously perform the charge pumping operations and thus the PLL clock signal NEW_CLK_PLL can rapidly reach the target frequency. That is, the locking time in accordance with the present invention is faster than the conventional locking time. The fast locking time means that the semiconductor device can more rapidly reach a stable operation state.

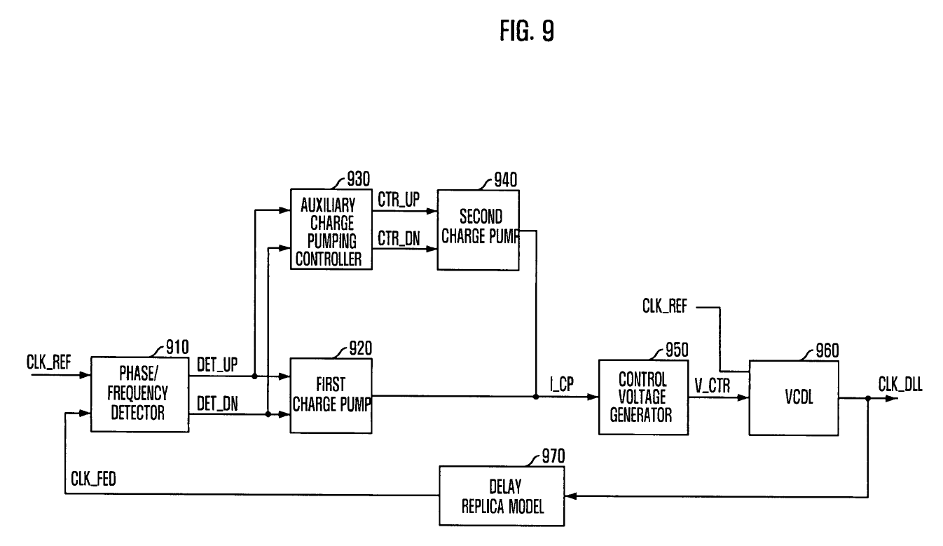

FIG. 9 is a block diagram of a delay locked loop (DLL) using the charge pumping circuit of FIG. 3.

Referring to FIG. 9, the DLL includes a phase detector 910, a first charge pump 920, an auxiliary charge pumping controller 930, a second charge pump 940, a control voltage generator 950, a voltage controlled delay line (VCDL) 960A, and a delay replica model 970.

The phase detector 910 detects a phase difference between a reference clock signal CLK_REF and a feedback clock signal CLK_FED to generate an up detection signal DET_UP and a down detection signal DET_DN corresponding to the detected phase difference. The reference clock CLK_REF is a signal corresponding to an external clock. The up detection signal DET_UP is a pulse signal activated when the phase of the feedback signal CLK_FED lags behind the phase of the reference clock CLK_REF, and it has a pulse width corresponding to the phase difference between the feedback signal CLK_FED and the reference clock CLK_REF. The down detection signal DET_DN is a pulse signal enabled when the phase of the feedback signal CLK_FED leads the phase of the reference clock CLK_REF, and it has a pulse width corresponding to the phase difference between the feedback signal CLK_FED and the reference clock CLK_REF.

The first charge pump 920 performs a positive charge pumping operation on an output terminal I_CP in response to the up detection signal DET_UP, and performs a negative charge pumping operation on the output terminal I_CP in response to the down detection signal DET_DN. That is, the first charge pump 920 charges the control voltage generator 950 in response to the up detection signal DET_UP, and discharges the control voltage generator 950 in response to the down detection signal DET_DN.

The auxiliary charge pumping controller 930 generates an up pumping control signal CTR_UP, which is activated during a predetermined section of the activation period of the up detection signal DET_UP, and a down pumping control signal CTR_DN, which is activated during a predetermined section of the activation period of the down detection signal DET_DN. That is, the up pumping control signal CTR_UP is a pulse signal activated from a time point where the activation period of the up detection signal DET_UP is longer than the predefined section to a deactivation time point of the up detection signal DET_UP. The down pumping control signal CTR_DN is a pulse signal activated from a time point where the activation period of the up detection signal DET_UP is longer than the predefined section to a deactivation time point of the up detection signal DET_UP.

The second charge pump 940 performs the positive charge pumping operation on the output terminal I_CP in response to the up pumping control signal CTR_UP, and performs the negative charge pumping operation on the output terminal I_CP in response to the down pumping control signal CTR_DN.

The control voltage generator 950 generates an oscillation control voltage V_CTR having a voltage level determined by the charge pumping operations of the first and second charge pumps 920 and 940. That is, the control voltage generator 950 charges electric charges in the positive charge pumping operation to generate the oscillation control voltage V_CTR of a high voltage level, and discharges electric charges in the negative charge pumping operation to generate the oscillation control voltage V_CTR of a low voltage level.

The voltage controlled delay line 960 generates a DLL clock signal CLK_DLL by delaying the reference clock signal CLK_REF by a delay time corresponding to the voltage level of the control voltage V_CTR, and provides the DLL clock signal CLK_DLL to the delay replica model 970.

The delay replica model 970 applies a delay of an actual clock path to the DLL clock signal CLK_DLL and outputs the feedback signal CLK_FED.

Prior to the locking of the DLL, especially when the phase difference between the reference clock signal CLK_REF and the feedback clock signal CLK_FED is large, much current flows through the output terminal I_CP by the charge pumping operations of the first and second charge pumps 920 and 940. Thereafter, a stable current flows through the output terminal I_CP by the charge pumping operation of the first charge pump 920. Consequently, the DLL in accordance with the embodiment of the present invention can ensure a fast locking time without degradation in a phase margin or operation characteristic with respect to jitters.

As described above, two charge pumps are provided in the PLL or the DLL. Thus, in the fast operation section (FST_SEC in FIG. 7) where the phase difference between the reference clock signal CLK_REF and the feedback clock signal CKL_FED is large, two charge pumps are operated to thereby reduce the locking time. Hence, the semiconductor device can more rapidly perform a normal operation. Furthermore, when the phase difference between the reference clock signal CLK_REF and the feedback clock signal CLK_RED is small, one charge pump is operated in the normal operation section NOR_SEC to thereby obtain a desired phase margin and operation characteristic with respect to jitters.

By changing a driving current of the charge pump in the locking operation, a fast locking time can be ensured without degradation in the phase margin or operation characteristic with respect to jitters. In addition, due to the fast locking time, a circuit operation can be stable more rapidly.

Furthermore, since the clock synchronization circuit obtains a desired phase margin, its stability can be increased.

Moreover, since the clock synchronization circuit obtains a desired operation characteristic with respect to jitters, an internal clock signal of a low jitter can be generated.

While the present invention has been described with respect to the specific embodiments, it will be apparent to those skilled in the art that various changes and modifications may be made without departing from the spirit and scope of the invention as defined in the following claims.

For example, although it has been described in the above-described embodiments that two inverters are used in the first and second delay elements 412 and 432 of FIG. 4, they can be replaced with other types of delay elements. Furthermore, positions and types of logic gates and transistors can be differently implemented according to polarities of signals input to the logic gates and transistors.

Moreover, although it has been described in the above-described embodiments that the improved charge pumping circuit is applied to the PLL or the DLL, the present invention can be applied to other circuits in which an amount of a current to be charge-pumped is changed according to situations.

What is claimed is:

1. A charge pumping circuit, comprising:
a first charge pump configured to perform a charge pumping operation on an output terminal in response to a first pumping control signal;
an auxiliary charge pumping controller configured to generate a second pumping control signal activated during a predetermined section of an activation period of the first pumping control signal; and
a second charge pump configured to perform a charge pumping operation on the output terminal in response to the second pumping control signal.

2. The charge pumping circuit as recited in claim 1, wherein the auxiliary charge pumping controller activates the second pumping control signal when the activation period of the first pumping control signal is longer than a predefined section.

3. The charge pumping circuit as recited in claim 2, wherein the auxiliary charge pumping controller comprises a pulse generating unit configured to generate the second pumping control signal that is activated after the predefined section from an activation time point of the first pumping control signal, and is deactivated at a deactivation time point of the first pumping control signal.

4. The charge pumping circuit as recited in claim 1, wherein the second charge pump performs a positive or negative charge pumping operation on the output terminal in response to the second pumping control signal.

5. The charge pumping circuit as recited in claim 1, wherein the first charge pump performs a positive or negative charge pumping operation on the output terminal in response to the first pumping control signal.

6. A clock synchronization circuit, comprising:
a phase detector configured to detect a phase difference between a reference clock signal and a feedback clock signal to output a detection signal corresponding to the detected phase difference;
a first charge pump configured to a charge pumping operation on an output terminal in response to the detection signal;
an auxiliary charge pumping controller configured to generate a pumping control signal activated during a predetermined section of an activation period of the detection signal;
a second charge pump configured to perform a charge pumping operation on the output terminal in response to the pumping control signal;
a control voltage generator configured to generate an oscillation control voltage in response to the charge pumping operations of the first and second charge pumps; and
a voltage controlled oscillator (VCO) configured to generate an internal clock signal corresponding to the oscillation control voltage and provide the feedback clock signal to the phase detector.

7. The clock synchronization circuit as recited in claim 6, wherein the auxiliary charge pumping controller activates the pumping control signal when the activation period of the detection signal is longer than the predefined section.

8. The clock synchronization circuit as recited in claim 7, wherein the detection signal comprises an up detection signal for performing a positive charge pumping operation on the output terminal and a down detection signal for performing a negative charge pumping operation on the output terminal, and the pumping control signal comprises an up pumping control signal for performing the positive charge pumping operation on the output terminal and a down pumping control signal for performing the negative charge pumping operation on the output terminal.

9. The clock synchronization circuit as recited in claim 8, wherein the auxiliary charge pumping controller comprises:
a first pulse generating unit configured to generate the up pumping control signal that is activated after the predefined section from an activation time point of the up detection signal and is deactivated at a deactivation time point of the up detection signal; and
a second pulse generating unit configured to generate the down pumping control signal that is activated after the predefined section from the activation time point of the down detection signal and is deactivated at the deactivation time point of the down detection signal.

10. The clock synchronization circuit as recited in claim 9, wherein each of the first and second pulse generating units comprises:
a delay unit configured to delay the detection signal by the predefined section; and
an output unit configured to output the pumping control signal in response to the detection signal and an output signal of the delay unit.

11. The clock synchronization circuit as recited in claim 8, wherein the second charge pump comprises:
a first current source configured to perform the positive charge pumping operation on the output terminal in response to the up pumping control signal; and
a second current source configured to perform the negative charge pumping operation on the output terminal in response to the down pumping control signal.

12. The clock synchronization circuit as recited in claim 8, wherein the up detection signal and the down detection signal are pulse signals having a pulse width corresponding to the phase difference between the reference clock signal and the feedback clock signal.

13. The clock synchronization circuit as recited in claim 8, wherein the up pumping control signal is activated when the activation period of the up detection signal is longer than the predefined section, and the down pumping control signal is activated when the activation period of the down detection signal is longer than the predefined section.

14. The clock synchronization circuit as recited in claim 6, wherein the VCO is configured to generate the internal clock signal having a frequency corresponding to the oscillation control voltage, and provides the internal clock signal as the feedback clock signal.

15. The clock synchronization circuit as recited in claim 6, wherein the VCO comprises:
a voltage controlled delay line (VCDL) configured to generate the internal clock signal by delaying the reference clock signal by a time delay corresponding to the oscillation control voltage; and
a delay replica model configured to apply a delay time of an actual clock path to the internal clock signal and output the feedback clock signal.

16. A method for operating a clock synchronization circuit, the method comprising:
performing a first charge pumping operation on an output terminal by using a first current during an activation period corresponding to a phase difference between a reference clock signal and an internal clock signal;
performing a second charge pumping operation on the output terminal by using second current during a predetermined section of the activation period; and
generating the internal clock signal according to the first and second charge pumping operations.

17. The method as recited in claim 16, wherein the second charge pumping operation is performed when the activation period is longer than a predefined section.

18. The method as recited in claim 17, wherein the second charge pumping operation is enabled after the predefined section from an enable time point of the first charge pumping operation, and is disabled at a disable time point of the first charge pumping operation.

19. The method as recited in claim 16, wherein each of the first and second charge pumping operations comprises:
performing a positive charge pumping operation on the output terminal; and
performing a negative charge pumping operation on the output terminal.

20. The method as recited in claim 16, wherein the second current is greater than the first current.
